(19) United States
(12) Patent Application Publication
(10) Pub. No.: US 2009/0250096 A1
(43) Pub. Date: Oct. 8, 2009

(54) Solar-To-Electricity Conversion Sub-Module

(76) Inventor: Eric Ting-Shan Pan, Fremont, CA (US)

Correspondence Address: J. NICHOLAS GROSS, ATTORNEY, 2030 ADDISON ST., SUITE 610, BERKELEY, CA, 94704, US

(21) Appl. No.: 12/417,931

(22) Filed: Apr. 3, 2009

Related U.S. Application Data
(60) Provisional application No. 61/043,014, filed on Apr. 7, 2008.

(51) Int. Cl. H01L 31/058; H01L 31/052

(52) U.S. Cl. 136/248; 136/246

(57) ABSTRACT

The invention addresses the area utilization and capital efficiency of systems for converting solar energy into electricity. A solid-state solar submodule includes photovoltaic and thermoelectric or thermionic cells. The submodule can be implemented in various configurations and by a solar insolation flux collection and concentration method to improve the area utilization and solar-to-electricity conversion efficiency. A thermal expansion matched multilayer board is also used to withstand ultra high concentration of solar insolation flux.

### FIELD OF THE INVENTION

The present invention relates to the field of solar electricity and, more particularly, to the collection and conversion of solar energy into electricity using submodules that use concentrated solar flux/insolation, and which can be assembled into larger solar energy conversion systems.

### BACKGROUND

The collection of solar energy including photonic and thermal energies within the solar spectrum and subsequent conversion to electric power have been explored for many applications including, but not limited to, photovoltaics, concentrating photovoltaics, thermophotovoltaics, solar thermal power, concentrating solar thermal power, active solar heating, and passive solar heating, cooling, solar thermo-electrochemical, and daylighting. In solar collection, there are a number of optical systems demonstrated for long-term reliability such as flat-plates, flat-plates with side reflectors, tubular collectors, paraboloids, parabolic troughs, Fresnel lens or reflectors, heliostats with a central receiver, and Stirling dishes with a refractance or a reflectance solar loss of typically 10%. These optical systems may or may not be integrated with a one-axis or two-axes solar tracking system.

The selection of an optical system depends on cost effectiveness, maintainability, cell materials, cell device and assembly, conversion efficiency, the degree of solar concentration, and the methods to collect and/or track the sun. The concentration factor of these optical system collectors is primarily limited by the temperature-dependent efficiency and thermal stability of solar conversion method whether it is a working fluid in solar thermal or a conversion device in solar photovoltaic. Among the top system performers at the time of this invention, Stirling dish that uses a gas has operated with a conversion efficiency at about 40% and a concentration over 2,000× for solar thermal power and a lens-based concentrator that uses a multi-junction solar cell has performed at about 40% conversion efficiency and 240× concentration factor. For multi-junction concentrator solar cells, it is found that conversion efficiency peaks out at about 600× before the thermal expansion mismatch and associated thermal effects of multiple stacking junctions or monolithically grown epitaxial layers become problematic. In particular, residual stresses induced by thermal expansion mismatch induce defects and degrade conversion efficiency and occur in both lattice-matched and metamorphic (lattice-mismatched) epitaxial layered multi-junction solar cell structures.

Examples of solar to electrical conversion systems can be seen in the following, all of which are hereby incorporated by reference herein:

U.S. Pat. No. 4,710,588 Ellion

U.S. Pat. No. 6,281,426 Olson, et al.

U.S. Pat. No. 7,109,408 Kucherov, et al.

U.S. Pat. No. 7,322,156 Rillie, et al.

U.S. Pat. No. 5,009,719 Yoshida

U.S. Pat. No. 7,335,835 Kukulka, et al.

U.S. Pat. No. 4,776,893 McLeod et al.

Ortiz, Estibaliz et al., “A high-efficiency LPE GaAs solar cell at concentrations ranging from 2000 to 4000 suns,”

Progress in Photovoltaics: Research and Applications, volume 11, issue 3 (Jan. 30, 2003), pp. 155-163.

The most significant obstacle to wide deployment of solar electricity has been the figure of merit in cost per watt or kilo-watt-hour generated by a given solar-to-electricity conversion method. Current methods for manufacturing the solar power generation require significant capital investment to realize volume production. Final products remain high in cost which has prevented penetration into the large utility and consumer markets as well as other niche markets. Contributing factors to cost include the conversion cell and its material, fabrication, package and assembly, frame and assembly, applicable solar ray collection apparatus such as concentrator and tracker, electrical system, transportation, and installation.

A key parameter is the conversion efficiency—the ratio of electrical power output over solar power impinging on the solar cell or module. Higher conversion efficiency means higher power output per unit collection area and lower cost per output power. Another key parameter is the concentration factor—the ratio of the concentrated solar radiation intensity at the focal area to the flux at its collector aperture or, equivalently, the ratio of the concentrated area at the focal point to the collector aperture area provided negligible loss of solar flux along the path of concentration optics. Higher concentration factor means smaller footprint of the conversion device and thus lower cost per output power.

Accordingly there is clearly a long-felt need for solar-to-electrical conversion systems (and components thereof) which are capable of addressing these deficiencies in the prior art.

### SUMMARY OF THE INVENTION

An object of the present invention, therefore, is to overcome the aforementioned limitations of the prior art. It will be understood from the Detailed Description that the inventions can be implemented in a multitude of different embodiments. Furthermore, it will be readily appreciated by skilled artisans that such different embodiments will likely include only one or more of the aforementioned objects of the present inventions. Thus, the absence of one or more of such characteristics in any particular embodiment should not be construed as limiting the scope of the present inventions.

A first aspect of the invention is directed to a solar-to-electricity conversion submodule comprising: a photon-to-electricity conversion device; a heat sink/pipe coupled to the photon-to-electricity conversion device; a multi-layer board having a light cavity for receiving or transmitting radiation flux associated with the photon-to-electricity conversion device; one or more conductive leads coupled to the photon-to-electricity conversion device for providing an electrical output in response to radiation flux impinging on the photon-to-electricity conversion device; wherein the photon-to-electricity conversion device, heat sink/pipe and conductive leads are located on and housed by or attached to the multi-layer board.

The photon-to-electricity device is preferably based on a single junction cell adapted to convert only a first portion of an insolation flux spectrum into electrical energy based on a first band gap energy. The module is further preferably adapted to be stacked into a cascade with one or more second modules having one or more photon-to-electricity devices based on single junction cells adapted to convert a second different portion of the insolation flux spectrum into electrical energy based on one or more second band gap energies. The cascade is arranged in a linear arrangement such that the insolation flux travels in a straight line, or in an offset arrangement such that the insolation flux is refracted and reflected between different photon-electricity devices as it travels.

The multi-layer board is further preferably adapted to mount a thermionic or thermoelectric device in lieu of or in addition to the photon-to-electricity device, and is comprised of a co-fired ceramic and conducting thermal vias, thermal diodes, bypass and/or blocking diodes, and embedded sensors and related electronic circuitry. In some embodiments the multi-layer board is further adapted to couple to a light tube, a light guide or light pipe to receive the radiation flux.

In some embodiments the photon-to-electricity device includes reflector or a single or more reflection coatings are for reflecting a remaining radiation flux that is not converted into electricity.

In other embodiments a plurality of photon-to-electricity devices having the same spectrum conversion capability are arranged within the same plane and in a line to receive the radiation flux in a broad focal line. The focal line can be created by, among other things, a slit or light cavity mounted on the multi-layer board.

In some embodiments the photon-to-electricity conversion devices are situated and paired in a plane with other matching photovoltaic cells, while other devices are situated and paired in a plane with respective matching photovoltaic cell, such that the concentrated insolation flux is converted by a a two dimensional array into electrical energy. The devices can be paired with cells orthogonally positioned as well such that the concentrated insolation flux is converted by a three dimensional array into electrical energy.

Another aspect of the invention concerns a solar-to-electricity conversion submodule comprising: a photon-to-electricity conversion device adapted to convert insolation flux into electricity; a thermionic and/or thermoelectric device with a single or multiple anti-reflection and/or reflection coatings for spectrum selectivity situated along the path of solar flux to convert heat energy into electricity or adjacent to the photon-to-electricity device and adapted to convert heat energy associated with such photon-to-electricity device into electricity; a heat sink/pipe coupled to both the photon-to-electricity conversion device and the thermionic and/or thermoelectric device; a multi-layer board having a light cavity for receiving or transmitting insolation flux; an electrical combiner circuit coupled to both the photon-to-electricity conversion device and the thermionic and/or thermoelectric device and adapted to generate an electrical output in response to the insolation flux; wherein the photon-to-electricity conversion device, thermionic and/or thermoelectric device, heat sink/pipe and electrical combiner circuit are located on and housed by the multi-layer board.

In preferred embodiments a position of the thermionic and/or thermoelectric device can be automatically adjusted. Also, the multi-layer board preferably has a thermal expansion characteristic matching the photon to electricity conversion device.

A further aspect of the invention is directed to a solar-to-electricity conversion submodule comprising: at least one photon-to-electricity conversion device having a single junction cell for converting only a first portion of an incident radiation spectrum into electricity; a heat sink/pipe coupled to the photon-to-electricity conversion device; a multi-layer board having a light cavity for receiving or transmitting radiation flux associated with the photon-to-electricity conversion device; wherein the multi-layer board is adapted to have a thermal expansion characteristic that substantially matches the photon-to-electricity conversion device; one or more conductive leads coupled to the photon-to-electricity conversion device for providing an electrical output in response to radiation flux impinging on the photon-to-electricity conversion device; wherein the photon-to-electricity conversion device, heat sink/pipe and conductive leads are located on and housed by the multi-layer board.

Other aspects of the invention are directed to a larger solar-to-electricity conversion system, in which the improvement comprises a photovoltaic subsystem including a plurality of photovoltaic cells having different band gaps to convert concentrated ultraviolet, visible, and infrared solar flux into electrical energy; and wherein the plurality of photovoltaic cells are configured in a cascade arrangement for processing the concentrated ultraviolet, visible, and infrared solar flux.

Preferably the cascade arrangement includes at least two photovoltaic cells arranged linearly such that the flux travels substantially in a straight line through the photovoltaic subsystem, or they are arranged with an offset such that the flux is refracted and reflected between successive cells in the photovoltaic subsystem.

Each of the plurality of photovoltaic cells preferably is made from liquid phase epitaxy or gas diffusion, and includes an anti-reflection coating and/or a reflection coating for spectrum selectivity of solar flux impinging on the device, one or more p-n junctions, one or more front conductor contacts, and one or more back conductor contacts for electrical, as well as contacts for heat conduction. The p-n junctions of the photovoltaic cells are preferably made of crystalline materials.

The cells can also include a single layer or multilayers of absorptive or anti-reflection costings for raising the absorption of a selective spectrum of the radiation flux that is converted into electricity.

In preferred embodiments a heat to electrical conversion subsystem is situated in a path of the ultraviolet, visible, and infrared solar flux and adapted to convert heat to electricity. The invention can be paired with tracking sensors and motor drives that orient the conversion system toward the sun. Automated positioning mechanisms can be employed for adjusting a spacing of the photon-to-electricity conversion devices.

Further aspects of the invention concern a solar-to-electricity conversion system comprising: a photovoltaic subsystem including at least two photovoltaic cells having different band gaps to convert concentrated insolation flux into electrical energy; at least two circuit boards for mounting and housing the at least two photovoltaic cells; wherein respective junctions of the at least two photovoltaic cells are on separate substrates or thin films situated on a respective circuit board; a frame adapted for supporting the at least two circuit boards and maintaining a first separation there between; wherein an electrical output can be generated based on the concentrated insolation flux.

In preferred embodiments of this type of system a light cavity can be coupled to one or more of the at least two circuit boards, the least two circuit boards are thermally matched to the respective at least two photovoltaic cells, have embedded thermal conduction components, and diodes and/or other electrical circuitry to optimize voltage and current maximums of electricity generated by the system.

Furthermore at least one of the least two photovoltaic cells can have a reflector for transmitting a remaining unconverted spectrum of the concentrated insolation flux to a subsequent separate photovoltaic cell. The concentrated insolation flux can received as a focal beam of a defined shape.

Another aspect of the invention addresses a solar-to-electricity conversion system comprising: a first photon-to-electricity conversion device adapted to convert a first spectrum portion of a concentrated insolation flux to electricity; the first photon-to-electricity conversion device being situated in a first position within a path of the concentrated insolation flux; a second photon-to-electricity conversion device situated adapted to convert a second spectrum portion of a remainder of the concentrated insolation flux to electricity; the second photon-to-electricity conversion device being situated in a second position separated from the first position within the path of the concentrated insolation flux; a heat to electrical conversion subsystem situated in a third position within the path of the concentrated insolation flux and including at least one of an array of thermoelectric cells and/or thermionic cells to covert heat associated with a third spectrum portion of the concentrated insolation flux into electric energy; a frame adapted for supporting the first and second photon-to-electricity conversion devices and the heat to electrical conversion subsystem; wherein electrical power can be derived from at least the first spectrum portion, the second spectrum portion and the third spectrum portion of the concentrated insolation flux.

The heat to electrical conversion subsystem can be situated in a variety of locations, including before the first photon-to-electricity conversion device and/or after a last one of the photon-to-electricity conversion devices within the concentrated insolation flux path. As alluded to above the first photon-to-electricity conversion device, the second photon-to-electricity conversion device, and the heat to electrical conversion subsystem can be configured or in an offset arrangement such that the concentrated insolation flux is refracted and reflected between one or more successive cells and/or the heat to electrical conversion subsystem.

The thermoelectric cells in the heat to electrical conversion subsystem preferably include: a cascade of crystalline thermoelectric cells of one or multiple types of junction materials absorbing infrared radiation or heat; and the thermoelectric cells further including a single or multiple anti-reflection and/or reflection coatings for spectrum selectivity, p-n junctions, front conductor contacts, and back conductor contacts for electrical and, separate heat conduction; and the p-n junctions of the thermoelectric cells are made of crystalline materials.

The thermionic cells in the heat to electrical conversion subsystem preferably include: a single or multiple anti-reflection and/or reflection coatings on the hot side for spectrum selectivity; an array of alternating n-type and p-type thermal diodes; wherein the thermal diodes are shaped into columns using a via structure embedded in a multilayer board; a hot side conductor contact; a cold side conductor contact; and electrical interconnect to couple the thermal diodes and electrical contacts.

Embodiments of the invention can be used to form a solar energy power generating plant.

Other aspects of the invention concern a photon-to-electricity subsystem comprising: a cascade of photovoltaic cells of different band gaps and each of one or more p-n junctions absorbing ultraviolet, visible, and infrared solar flux; the photovoltaic cells including optical coatings, p-n junctions, and conductor contacts for electrical and heat conduction; wherein the p-n junctions of the photovoltaic cells are made of crystalline materials; and the photovoltaic cells being mounted on a multilayer board of cofired ceramic.

Another aspect of the invention is directed to a solar-to-electricity conversion system configured in a modular platform and comprising: a photon-to-electricity subsystem including an array of successive spaced photovoltaic cells having different band gaps to convert concentrated insolation flux within a flux path into electrical energy; a heat-to-electricity conversion subsystem also situated within the flux path and including at least one of an array of thermoelectric cells or thermionic cells to covert heat into electric energy; a heat sink/pipe coupled to the photon-to-electricity subsystem and/or the heat-to-electricity conversion subsystem; a plurality of thermal expansion matched multilayer boards for integrating the photon-to-electricity subsystem, the heat-to-electricity conversion subsystems and heat sink/pipe; a light cavity situated within the flux path and adapted to direct the concentrated insolation flux between the successive spaced photovoltaic cells; and an assembly for mounting the photon-to-electricity subsystem, the heat-to-electricity conversion subsystem, the heat sink/pipe, the plurality of thermal expansion matched multilayer boards and the light cavity.

A further aspect concerns a solar-to-electricity conversion system configured in a modular platform and comprising: a photon-to-electricity subsystem including a linear cascade arrangement of two or more successive spaced photovoltaic cells, each of the cells having a different band gap to convert concentrated insolation flux within a flux path into electrical energy; a heat-to-electricity conversion subsystem also situated immediately before or after the photon-to-electricity subsystem within the linear cascade arrangement and flux path and including at least one of an array of thermoelectric cells or thermionic cells to convert heat into electric energy; a heat sink/pipe coupled to the photon-to-electricity subsystem and/or the heat-to-electricity conversion subsystem; a plurality of thermal expansion matched multilayer boards, one for each of the photovoltaic cells and the array of thermoelectric or thermionic cells; and a casing assembly for mounting the photon-to-electricity subsystem, the heat-to-electricity conversion subsystem, the heat sink/pipe, the plurality of thermal expansion matched multilayer boards and the light cavity.

In preferred embodiments the two or more successive spaced photovoltaic cells include the following: a first photovoltaic cell of band gap at about 2.54 eV; a second photovoltaic cell of band gap at about 1.47 eV; and a third photovoltaic cell of band gap of about 0.7 eV. Furthermore the first photovoltaic cell is AlGaAs; the second photovoltaic cell is GaAs; and the third photovoltaic cell is GaSb or Ge.

Yet another aspect concerns a solar-to-electricity conversion system configured in a modular platform and comprising: a photon-to-electricity subsystem including an offset cascade arrangement of two or more successive spaced photovoltaic cells, each of the cells having a different band gap to convert concentrated insolation flux within a flux path into electrical energy; wherein the concentrated insolation flux is reflected between successive photovoltaic cells as it traverses the offset cascade arrangement; a heat-to-electricity conversion subsystem situated immediately before the photon-to-electricity subsystem for reflecting the concentrated insolation flux into the offset cascade arrangement and including at least one of an array of thermoelectric cells or thermionic cells to convert heat into electric energy; a heat sink/pipe coupled to the photon-to-electricity subsystem and/or the heat-to-electricity conversion subsystem; a plurality of thermal expansion matched multilayer boards, one for each of the photovoltaic cells and the array of thermoelectric or thermionic cells; a casing assembly for mounting the photon-to-electricity subsystem, the heat-to-electricity conversion subsystem, the heat sink/pipe, and the plurality of thermal expansion matched multilayer boards.

Another aspect of the invention is directed to a solar-to-electricity conversion system configured in a modular platform and comprising: a first light directing means for receiving concentrated insolation flux; a photon-to-electricity subsystem including an offset cascade arrangement of two or more successive spaced photovoltaic cells, each of the cells having a different band gap to convert the concentrated insolation flux within a flux path into electrical energy; second light directing means positioned between the two or more successive spaced photovoltaic cells; wherein the concentrated insolation flux is reflected between the successive photovoltaic cells within the second light directing means as it traverses the offset cascade arrangement; a heat-to-electricity conversion subsystem situated immediately before the photon-to-electricity subsystem for reflecting the concentrated insolation flux into the linear cascade arrangement and including at least one of an array of thermoelectric cells or thermionic cells to convert heat into electric energy; a heat sink/pipe coupled to the photon-to-electricity subsystem and/or the heat-to-electricity conversion subsystem; a plurality of thermal expansion matched multilayer boards, one for each of the photovoltaic cells and the array of thermoelectric or thermionic cells; and a casing assembly for mounting the photon-to-electricity subsystem, the heat-to-electricity conversion subsystem, the heat sink/pipe, the plurality of thermal expansion matched multilayer boards and at least the second light directing means.

Still another aspect concerns a solar-to-electricity conversion system configured in a modular platform and comprising: a photon-to-electricity subsystem including a linear cascade arrangement of two or more successive spaced photovoltaic cells, each of the cells having a different band gap to convert concentrated insolation flux within a flux path into electrical energy; a heat-to-electricity conversion subsystem situated immediately before the photon-to-electricity subsystem for reflecting the concentrated insolation flux into the linear cascade arrangement and including at least one of an array of thermoelectric cells or thermionic cells to convert heat into electric energy; a heat sink/pipe coupled to the photon-to-electricity subsystem and/or the heat-to-electricity conversion subsystem; a plurality of thermal expansion matched multilayer boards, one for each of the photovoltaic cells and the array of thermoelectric or thermionic cells; and a casing assembly for mounting the photon-to-electricity subsystem, the heat-to-electricity conversion subsystem, the heat sink/pipe, and the plurality of thermal expansion matched multilayer boards.

A further aspect of the invention is directed to a solar-to-electricity conversion system configured in a modular platform and comprising: a photon-to-electricity subsystem including a first linear cascade arrangement of two or more successive spaced photovoltaic modules, each of the modules having a different band gap to convert concentrated insolation flux within a focal line into electrical energy; wherein the photovoltaic modules each include one or more photovoltaic cells situated in a planar arrangement within the focal line; a heat-to-electricity conversion subsystem situated immediately before or after the photon-to-electricity subsystem within the focal line and including at least one of an array of thermoelectric cells or thermionic cells to convert heat from the concentrated insolation flux into electric energy; a heat sink/pipe coupled to the photon-to-electricity subsystem and/or the heat-to-electricity conversion subsystem; a plurality of thermal expansion matched multilayer boards, one for each of the photovoltaic cells and the array of thermoelectric or thermionic cells; a casing assembly for mounting the photon-to-electricity subsystem, the heat-to-electricity conversion subsystem, the heat sink/pipe, the plurality of thermal expansion matched multilayer boards and the light cavity.

Still another aspect concerns a solar-to-electricity conversion system configured in a modular platform and processing concentrated solar insolation flux incidence into the solar-to-electricity conversion system with a concentration factor between 250× and 5,000× comprising: a photovoltaic subsystem including an array of photovoltaic cells of different band gaps and each cell having an area between about 300 hundred square microns to 30 square centimeters to convert concentrated solar visible, ultraviolet, and infrared radiation into electrical energy; a thermoelectric or a thermionic subsystem including a plurality of thermoelectric or thermionic cells to convert at least the concentrated solar infrared radiation and/or a temperature gradient into electrical energy; a frame adapted to support and function as an environmental shield and which is integrated as part of the hot side and/or cold side (heat sink) in the heat-to-electricity conversion; a first light directing means for directing the concentrated solar insolation flux incidence and any reflectance unto the photovoltaic and thermoelectric or thermionic subsystems; a thermal expansion matched multilayer board adapted to integrate components (a) and (b) and to transfer heat among such components by thermal vias; and a second light directing means in the multilayer board adapted to direct concentrated solar insolation flux between photovoltaic cells.

Other aspects of the invention concern methods of converting concentrated ultraviolet, visible, and infrared solar flux to electrical energy using the above architectures and configurations. In addition the solar insolation flux can be collected by one or more of: a dome of a Fresnel lens system, a parabolic trough parabolic trough, a linear Fresnel lens, a hemispherical bowl collector, a flat absorbing plate, a cylindrical collector, or an active steering or a motion-free tracking collector with concentration or spectrum splitting function. From there it is presented to a cascade of photon-to-electricity devices and/or heat-to-electricity devices. The electrical energy generated can be used to charge an electric storage apparatus, or be delivered to a balance-of-system for delivering electricity.

Other aspects of the invention concern a production method for making crystalline photovoltaic cells and/or thermoelectric or thermionic cells the improvement comprising forming the crystalline photovoltaic and/or thermoelectric or thermionic cells and interfaces by liquid-phase epitaxial growth, gas diffusion, or some other equivalent process. The process further preferably includes a step of growing a seed layer and/or a sacrificial layer using metalorganic chemical vapour deposition (MOCVD) or an epitaxy growth method.

While described in the context of a solar conversion system, it will be apparent to those skilled in the art that the present teachings could be used in any number of other systems in which it is desirable to improve efficiency of a radiation conversion process. Embodiments of the invention are expected to be used for both terrestrial and extra-terrestrial applications where it is desired to make use of solar power—such as part of a satellite, a space transport, robotic exploration vehicle, a housing unit, a building, a solar power plant, space station, a solar power plant, off-grid and grid-connected facilities, etc.

### DESCRIPTION OF THE DRAWINGS

FIG. 1 is a simplified diagrammatic view of a preferred embodiment of a solid-state solar engine system of the present invention;

FIG. 2A is an illustrative configuration of a preferred embodiment of a solar-to-electricity converter module;

FIG. 2B is an illustrative configuration of an alternate embodiment of a solar-to-electricity converter module in which a thermoelectric/thermionic device is coupled to one or more photoelectric device;

FIG. 3A is a diagrammatic view of common components of a preferred embodiment of a packaged cell;

FIG. 3B is an illustrative configuration of an alternate embodiment of a cell in which a thermoelectric/thermionic device is coupled to a photoelectric device;

FIG. 3C is a cross sectional view of a packaged sub-module;

FIG. 4 is a diagrammatic view of a converter module according to one embodiment of the present invention;

FIG. 5 is a diagrammatic view of a second embodiment of a converter module;

FIG. 6 is a diagrammatic view of a third embodiment of a converter module;

FIG. 7 is a diagrammatic view of a fourth embodiment of a converter module;

FIG. 8 is a diagrammatic view of a fifth embodiment of a converter module;

### DETAILED DESCRIPTION

A novel modular platform integrates solid-state photovoltaic and thermionic or thermoelectric devices with the solar collection and concentration optics for the solar-to-electricity conversion. Both the conversion efficiency and the heat handling capability under a focal area of high solar concentration are increased by cascading photon-to-electricity devices such as photovoltaic devices and heat-to-electricity devices such as solid-state thermionic and thermoelectric devices, each of which is made of specific composition.

Embodiments of the present invention thus provide a conversion system that is scalable for the photovoltaic device of area from a few hundreds of micron square to a few tens of centimeter square with the corresponding optical collection area that gives a concentration factor from 250× to 5,000×. The overall conversion efficiency of the solid-state solar engine module of the present invention has potential to achieve 50% or more of which the conversion from photon to electricity is greater than 40% and the conversion from heat to electricity is greater than 10%.

The present disclosure describes an alternative solution to the prior-art multi-junction solar cell or photovoltaic cell. The problem of thermal expansion mismatch in the multi-junction solar cell occurs between different constituent layers under elevated temperature that leads to thermal residual stresses, which affect the integrity and lifetime of the photovoltaic cells, under high concentrated solar flux. It is known for a single-crystal cell under no external influence, its coefficient of thermal expansion (CTE) is complaint with the crystal symmetry.

A single-crystal photovoltaic cell as used in preferred embodiments of the present invention can, therefore, handle higher concentrated solar flux and temperature than the prior-art multi-junction photovoltaic cells. The modular platform described herein arranges the single-crystal photovoltaic cells to absorb solar flux in a cascade such that the first cell absorbs a portion of the solar flux with energy above its band gap and the second cell absorbs, with energy above the second cell's band gap, a portion of the solar flux that is not absorbed by the first cell, and so on. For semiconductor-based photovoltaic materials, the band gap generally refers to the energy difference between the top of the valence band and the bottom of the conduction band.

Furthermore, preferred embodiments exploit the conversion of thermal energy to electric energy using thermoelectric and thermionic converters. In particular, a prior art solid-state thermionic converter using semiconductor diode has sufficient high power densities and efficiencies and can operate at temperature range for a broad scope of application potentials. In some embodiments the solar energy converter comprising the aforementioned cascading single crystal photovoltaic cells and the solid-state thermionic devices utilizes and transfers heat from the interaction between solar flux and a solid-state matter to a solid-state thermionic device for heat-to-electricity conversion.

Another advantage of certain preferred embodiments is that a single crystal cell of high quality can be fabricated with a method that forms a layer interface of true thermodynamic equilibrium such as by using a prior-art liquid-phase epitaxy method that is not currently used for the mass production of solar cells. The liquid phase epitaxy method may be improved for mass production with active epitaxy growth control and high throughput layer formation mechanism. Among other aspects the present invention proposes a new application by using an improved liquid phase epitaxy method for the mass production of high quality single crystal solar cells with low dislocations and defects and uniform layers and interface. High crystal quality yields significant advantage with high conversion efficiency because of low defect density and exceptional optical quality because of high degree of homogeneity and interfacial uniformity.

Finally, another useful aspect of embodiments of the invention is that the the solar energy converter can be fabricated with a method that is fully compatible with conventional low-temperature cofired ceramic process technology for assembling the cells into packages. The coefficient of thermal expansion of low-temperature cofired ceramic can be matched to that of the solar-to-electricity conversion die attached to it for thermal stability under high solar concentration. A customized light cavity can be incorporated into the low-temperature cofired ceramic process for special module configurations.

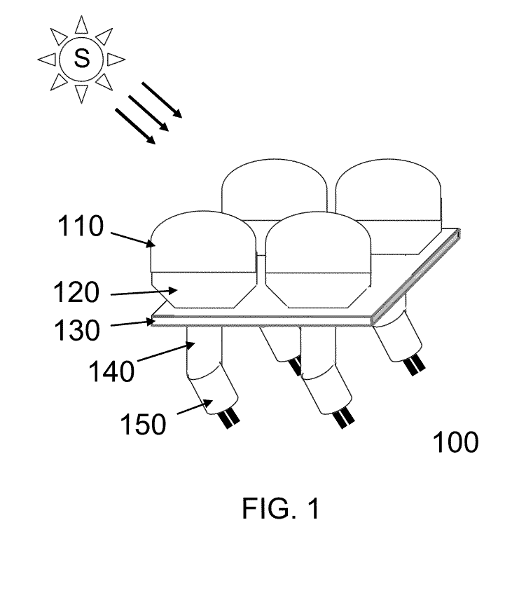

Referring initially to FIG. 1 a preferred embodiment of a solar-to-electricity conversion system 100 according to the present invention is shown. It will be understood by those skilled in the art that the depiction provided is not intended to show exact dimensions, shapes, and/or proportions as may be used in a commercial application.

The system 100 generally includes a collector 110, a concentrator 120, a frame 130, a light tube/guide/fiber/pipe 140, and a converter module 150 which is the subject of substantial discussion below. It will be apparent to those skilled in the art that the present discussion is simplified in order to elaborate the main aspects of the invention, and that other elements could be employed as well in other embodiments depending on system requirements.

Collector 110 is preferably one of a conventional dome of a Fresnel lens system with high optical conversion to collect low and high angle solar rays (or other radiation source). Alternatively a combined optical system can be used for the dual purposes of a collector and a concentrator such as an active steering collector or a motion-free tracking collector with concentration or spectrum splitting function.

Concentrator 120 is preferably one of the following: a conventional parabolic trough/reflector, a set of two reflectors, a linear Fresnel lens, a hemispherical bowl collector, a cylindrical collector, a focusing lens, a tapered light tube, a light guide, a light fiber, or a light pipe for directing all the photons collected after the collector 110 to a focal area such as a focal spot or a focal line that is reduced from the collector aperture area by approximately the concentration ratio.

Frame 130 is preferably comprised of planks, frames, conduits, enclosures, racks or other suitable structures and is mounted on a roof-top, a stand, a tracking mount, a cladding, or any supporting structure for optimal solar collection and structure support of the entire system 100. The frame 130 may be configured to serve to shield the light tube/guide/fiber/pipe 140 and the converter module 150 from environmental factors such as air temperature, air humidity, water, wind, etc. The frame 130 may also be configured as a part of heat sinks/pipes for the photovoltaic conversion. The frame 130 may further serve in a preferred modular configuration to be integrated into the thermionic and thermoelectric conversion as part of a hot side or a cold side. In some embodiments frame 130 may even further consist of separate layers or regions as a hot side and a cold side for the thermionic and thermoelectric conversion.

Light tube 140 is preferably a conventional apparatus for guiding light rays from the concentrator 120 to the converter module 150.

Other examples will be apparent to those skilled in the art for components 110-140, and it is expected that the particular components and configuration will vary substantially from application to application depending on performance requirements, cost constraints, etc. Moreover while certain current conventional examples of such components have been described, it will be understood that the present invention can be used with other variants, advances, etc. of such components which are not yet well known and/or undiscovered.

In addition solar conversion system 100 can be integrated into a conventional balance-of-system typically composed of charge control, storage, inverter, electrical cabling, and protection circuitry for off-grid and on-grid applications. Energy storage (not shown) may use prior-art direct electric storage such as ultracapacitors or electrochemical energy storage such as batteries.

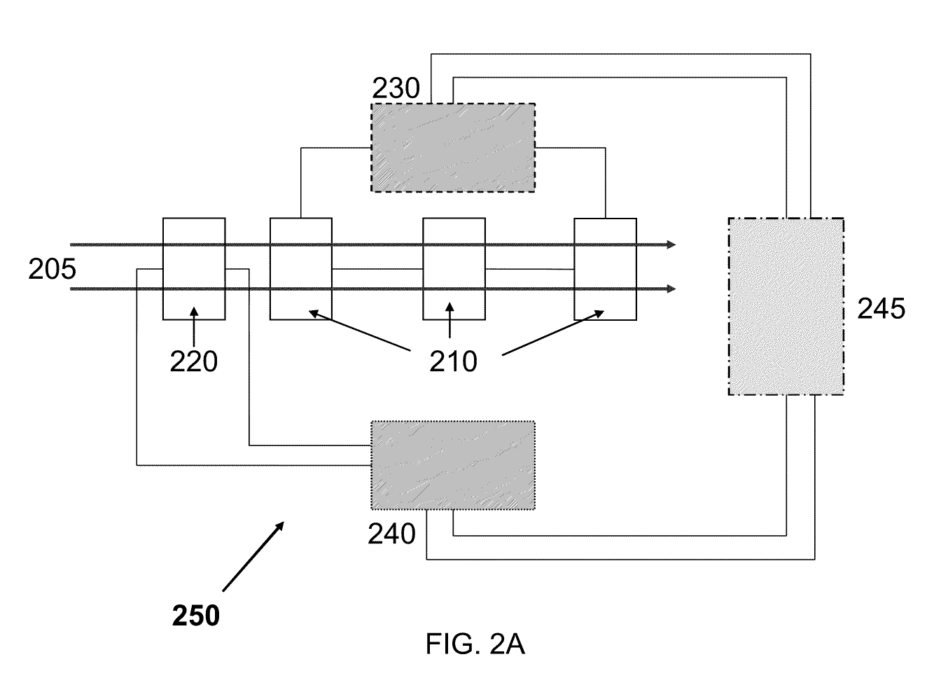

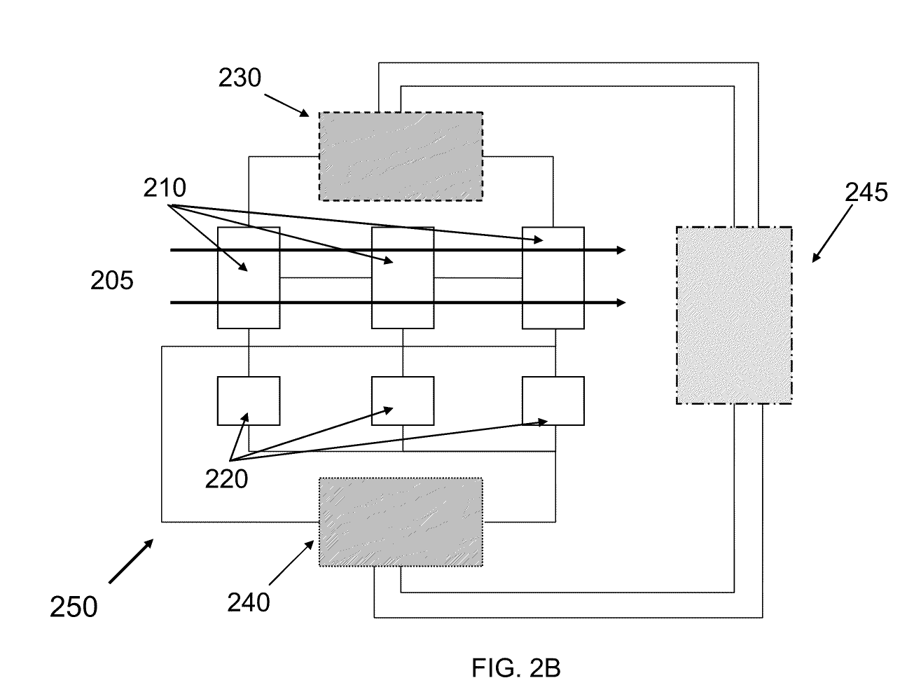

A preferred embodiment of a solar-to-electricity converter module 250 is illustrated in FIG. 2A. The converter module 250 provides a novel method and apparatus to improve conversion efficiency, concentration factor, and thermal handling capability. Again for illustrative purposes the present diagram and discussion is simplified and skilled artisans will appreciate that other components could be employed in deployed application.

Radiation 205 (preferably solar flux) falls on the converter module as a source of photons to be converted to electricity. Preferably the converter module 250 comprises a cascade arrangement of one or more photon-to-electricity devices 210, one more heat-to-electricity devices 220, a first power control circuit 230 for photon-to-electricity charge control, a second power control circuit 240 for heat-to-electricity charge control, and a circuit combiner 245 as part of the balance-of-system that may be placed external to a unit module.

The first power controller circuit 230 can be arranged such that the photocurrent and photovoltage from each photon-to-electricity device 210 can be combined within a solar-to-electricity converter module or connected in parallel or series with devices of other modules (shown in FIG. 1) to form the next levels of integration as in a panel and an array (not shown) for desired electrical characteristics. The solar radiation 205, consisting of a first spectrum of energetic photons, impinges on the cascade of photovoltaic devices 210 and a thermoelectric or thermionic device 220.

The thermoelectric or thermionic device 220 is preferably placed within the cascading order so that solar radiation incidence can be extracted from a position before the first photovoltaic device 210, after the last such device, or in both locations. Coatings such as that absorb infrared and/or ultraviolet and reflect visible may be applied on the surface of the thermoelectric or thermionic device upon which solar radiation incidence hits. The thermoelectric or thermionic device thus captures and converts thermal energy from that portion of the spectrum which would otherwise not be sufficient to activate electrons from the valence band to the conduction band across a band gap in a photovoltaic device. It will be understood of course that the heat energy converter is optional and will not be necessary or required in many installations.

An alternative embodiment for the conversion module 250 is shown in FIG. 2B. In this configuration the thermoelectric/thermionic devices 220 are directly physically/mechanically coupled to the photovoltaic devices 210, and extract heat that is associated with such devices, rather than deriving directly from within the solar flux beam. In some embodiments the positioning of the thermoelectric or thermionic device 220 can be adaptively varied (by an automated mechanical positioning system) in accordance with an optimal behavior observed at a particular location/installation/time of year. It will be understood by those skilled in the art that other embodiments may utilize features from both of these approaches, and the invention is not so limited.

Although the solar spectrum and photonic device physics are well known in the art and many prior-art photovoltaic cells with various compositions and band gaps have been fabricated, the present invention provides further improvement to the photon-to-electricity conversion efficiency and the concentration factor through a modular platform capable of integrating the photon-to-electricity and heat-to-electricity conversion devices. Unlike a conventional prior-art multi-junction solar cell that operates with limited concentration factor and operating temperature because of thermal expansion mismatches between the dissimilar constituent layers in a monolithic die and other thermal effects associated with temperature-dependent material properties such as series resistance, band gap, and built-in voltage, the present invention uses multiple single crystal cells of different compositions and thicknesses that the combined scheme can absorb equal or larger amounts of solar spectrum than the prior art multi-junction solar cells under significantly higher concentration.

Prior-art single-junction solar cells made of single crystal, polycrystalline, or amorphous layers are limited to wavelengths within a portion of the solar spectrum corresponding to their respective band gaps for solar absorption and conversion. The present invention preferably arrange single junction, single crystal devices to absorb solar flux in a cascade arrangement. In a simple example of such configuration a first cell absorbs wavelengths within a first portion of the solar flux with energy above its first band gap, a second cell absorbs energy above its respective second band gap, and so on. The cells are configured so that a portion of the solar flux that is not absorbed by the first cell is nonetheless absorbed by one or more subsequent cells in the cascade. In this fashion, a larger portion (a greater number of wavelengths) of the entire radiation spectrum can be utilized and converted to electrical form.

Prior-art tandem cells are typically made of two different photovoltaic cells mechanically stacked on top of each other. Preferred embodiments of the invention increase the number of cascading cells and add a variety of modular configurations. Different modular configurations may include photovoltaic cells of single p-n junction or a combination of single-junction cells with double-junction cells or even multi-junction cells to maximize full solar spectrum utilization and to optimize among cost, concentration factor, thermal management, and reliability.

Preferred embodiments of the invention also provide a novel scheme to transfer the heat from the interaction of solar flux 205 with the hot side of a thermionic or thermoelectric device 220 arranged along the solar ray path of the cascade. While FIG. 2A shows the solar flux travelling in a straight line for ease of illustration, it will be understood that the actual route may vary according to design constraints. By converting both photonic energy 230 and heat 240 and combining the two into converted electricity 245, the present invention achieves higher overall conversion efficiency under high solar concentration. The compositions of the photon-to-electricity conversion devices 210 in the present invention are preferably chosen to realize desired band gaps for absorbing all or most of solar spectrum of radiation.

For example, a simple cascading arrangement of photovoltaic cells is preferably structured so that the solar flux incidence impinges first on a AlGaAs photovoltaic cell of band gap at about 2.54 eV for the absorption and conversion of solar photons of wavelengths from blue/green to near ultraviolet and then on to a second GaAs photovoltaic cell of band gap at about 1.47 eV for the absorption and conversion of photons of wavelengths from orange/red to green/yellow and further on to a third GaSb or Ge photovoltaic cell of band gap close to 0.7 eV for the absorption and conversion of photos of wavelengths from medium infrared to red/near infrared. It will be apparent to those skilled in the art that other materials of elemental (including silicon), binary, ternary, quaternary, or higher number of elements in compositions may be utilized to optimize the number of sub-modules and the order of cascading sub-modules and to maximize the solar-to-electricity conversion efficiency.

While the present discussion provides an example of three (3) cascaded sub-modules, it will be apparent to those skilled in the art that the principles of the invention can be generally applied to any number of stages depending on the desired cost and performance requirements. Furthermore in some embodiments it may be desirable to have overlap in band gap coverage between one or more successive sub-modules or stages. Still further, in some embodiments where the thermal management of cells under concentration is able to maintain cells below each cell's junction temperature, the photovoltaic cells in the cascade may be made of single-junction, double-junction, and/or multi-junction.

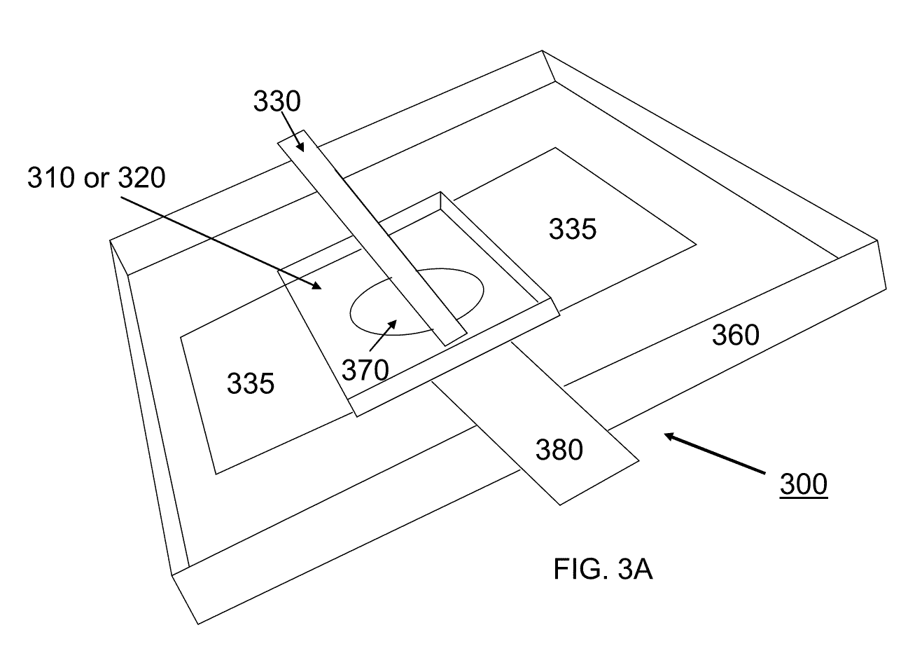

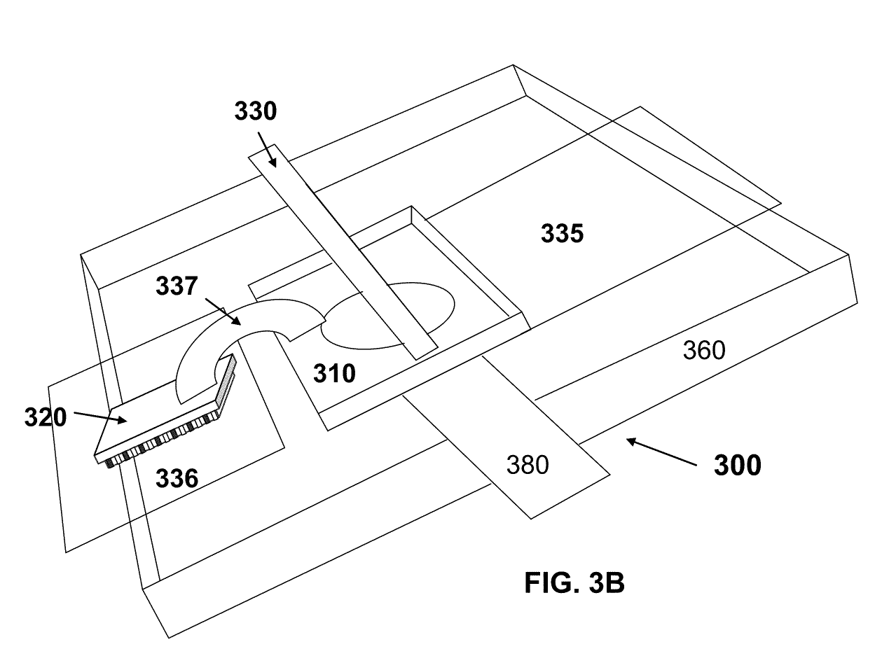

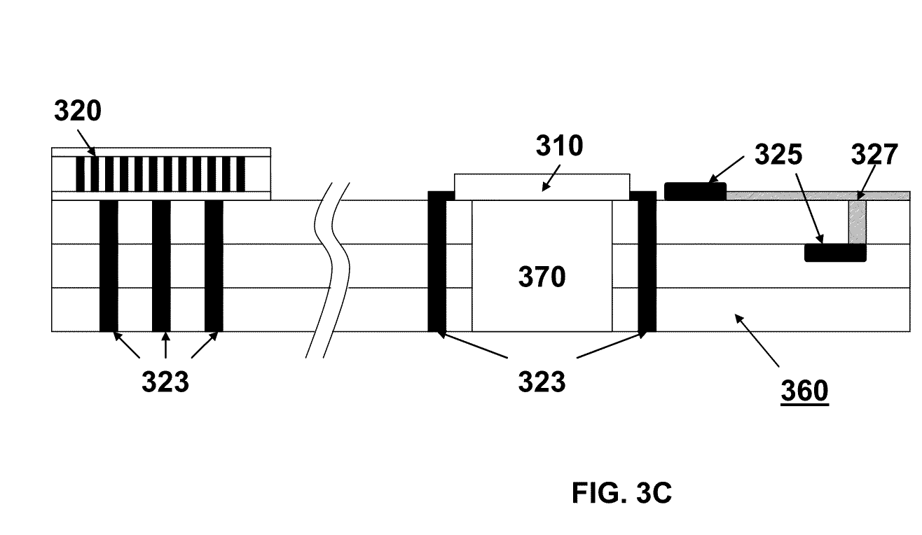

A preferred embodiment of a packaged sub-module 300 according to the present invention is illustrated in FIG. 3A. The packaged sub-module 300 is a building block of the converter module as in FIG. 1 and preferably includes a conductor 330 preferably made of indium tin oxide, gold, copper, or other materials of high electrical conductivity, a heat-to-electricity conversion device 320 and/or a photon-to-electricity conversion device 310, a heat sink/pipe 335, a multilayer board 360, a light cavity 370, as appropriate, for radiation transmission, and another conductor 380 which is preferably set to an opposite polarity from conductor 330 or a bias voltage between conductors 330 and 380 forming an electrical circuit under normal operating conditions. Note that the size, shape and configuration of the components is merely illustrative, and no assumptions or limitations should be drawn from these specific depictions.

The photon-to-electricity conversion device 310 is preferably connected with two electrical conductors 330 and 380 of opposite polarity for the collection of photocurrent and the generation of a DC photovoltage when photons in the solar flux, S, are absorbed. The photon-to-electricity conversion device 310 preferably is a photovoltaic cell or an array of photovoltaic cells. The photon-to-electricity conversion device 310 is preferably positioned in the direct path of the radiation—in this case solar rays from a light tube/guide/fiber/pipe 140 (as in FIG. 1) and again is preferably a photovoltaic device adapted to absorb a partial range of solar spectrum or energy, S, and to convert such to electricity.

In fact, for a given semiconductor material, the solar flux (or other radiation source) of photons of different energies penetrate different distances as a function of solar energy or wavelength-dependent absorption coefficient. Different semiconductor materials exhibit different absorption coefficient curves and usually have an abrupt edge in their absorption coefficient curves, corresponding to the photons of energy below the band gap that do not have sufficient energy to raise an electron across the band gap. Consequently these photons are not absorbed and are instead transmitted through the material. Thus photons having energy above the band gap have sufficient energy to raise an electron across the band gap and are absorbed.

Therefore, for a photovoltaic device, photons in the impinging solar flux, S, of energy, in eV, greater than or equal to the band gap of the active p-n junction will be absorbed so that an amount of solar energy equal to the band gap is converted to electricity. Some photons of energies greater than the band gap are re-emitted as heat or light, and it may be desirable to capture this type of heat energy as well as mentioned herein. Photons of energy less than the band gap of the active p-n junction will mostly transmit (not be absorbed) through the active p-n junction.

Preferred embodiments of the present invention provide a new type of converter module that, in addition to the conversion of solar flux of photons, preferably also converts heat into electricity. Heat is usually generated from the subsequent interactions between transmitted light and device materials and is typically associated with the transfer of absorbed light energy into heat through atomic vibration in the lattice structure. This can occur when incident photons have energy in excess of that of the bandgap of the material in question. In preferred embodiments of the invention, a thermal conversion can be done for those portions of the concentrated solar insolation spectrum situated both below and above the bandgaps covered by the photovoltaic devices.

As noted earlier, the heat-to-electricity conversion device is preferably positioned in the direct path of the solar flux, S, and preferably is a thermoelectric or thermionic device 320. Thus as seen in FIG. 3A, the sub-module can accommodate either a photovoltaic device 310 or a thermionic or thermoelectric device 320 within the radiation path. However, as noted earlier in some embodiments (see FIG. 3B) the thermoelectric or thermionic device 320 may not lie directly within the flux, and, instead, may be extracting heat primarily from the photovoltaic device 310 instead. In FIG. 3B a thermoelectric or thermionic device 320 is coupled by a heat extraction member 337. An additional heat sink/pipe 336 can be employed as well if desired depending on the relative heat dissipation needs/characteristics of devices 310 and 320.

A prior-art thermoelectric device responds to a temperature gradient or the absorption of infrared radiation (heat) with a voltage at the interface of dissimilar semiconductors that creates a current flow through the circuit (the external load) via the Seebeck effect. A prior-art thermionic device, by adding solid-state p-n junctions (as emitter-base and collector-base junctions) to conventional thermoelectric semiconductor (as base), responds to a temperature gradient between an emitter (hot) side and a collector (cold) side and Fermi level discontinuities at the interfaces between the emitter and a semiconductor barrier and the semiconductor barrier and a semiconductor gap material with a potential difference, which may drive current flow through the circuit (the external load).

More specifically, preferred embodiments of the invention provide a novel heat transferring mechanism that preferably uses a thermal expansion matched low-temperature cofired ceramic, high-temperature cofired ceramic (or an equivalent) multilayer board 360 to the solar-to-electricity conversion device with metal-filled or other conducting thermal vias (not shown) to transfer heat. This heat can then also be converted into electricity to supplement the overall radiation conversion operation.

As shown in FIG. 3A, the hot side of the heat-to-electricity conversion device 320 is preferably positioned in the direct path of solar flux, and has a single layer or multilayers of absorptive and reflective coatings (not shown). The cold side of the heat-to-electricity conversion device 320 is connected to a heat sink/pipe 335 that is preferably coupled to the multilayer board 360 and the frame 130 (shown in FIG. 1).

The heat sink/pipe 335 may be embodied with a number of different materials, dimensions, shapes, proportions, densities, and configurations depending on cost/performance requirements. As such, heat from the solar interaction with the hot side of device 320 is preferably not wasted but instead used for electricity generation.

Photon-to-electricity conversion device 310 and heat-to-electricity device 320 are preferably constructed from one or more p-n junctions. The p-n junctions can be formed by a low-cost material growth method such as prior-art liquid-phase epitaxy (LPE), gas diffusion, or an equivalent method on a crystalline substrate material; of course other techniques known in the art can also be used if desired. While LPE has been used in the past for LED manufacture, the Applicant is unaware of any prior implementation for solar cell technology. This technique is expected to be particularly useful for this type of device, and can result in substantially greater wafer throughput figures. The solid-state p-n junction or thermal diodes in the thermoelectric/thermionic devices can also be made using such technology.

FIG. 3B shows another embodiment for the conversion sub-module 305. The hot side of the heat-to-electricity conversion device 320 is preferably connected to the front side of the photon-to-electricity conversion device 310 with a heat conductor 337 that is preferably one of the following: conducting ribbons, wires, and/or thermal vias. While shown as a single structure, it will be understood that multiple individual members may be used for the heat conductor. The heat conductor 337 is preferably not connected electrically to the front side electrical conductor 330. The heat conductor 337 may optionally connect one or multiple heat-to-electricity conversion devices 320 to the photon-to-electricity conversion device 310. The heat sink/pipe 336 connected to the cold side of the heat-to-electricity conversion device 320 is preferably separate from the heat sink/pipe 335 for the photon-to-electricity conversion device 310.

Furthermore, in a novel scheme, columns of n- and p-type thermal diodes for the thermoelectric or thermionic devices 320 are preferably formed and shaped using a via structure (not shown) which is on or embedded in multilayer board.

As shown in a cross section in FIG. 3C, a multilayer board 360 is preferably used to house the packaged sub-module that may include the the heat-to-electricity conversion device 320, the photon-to-electricity conversion device 310, the light cavity 370 in configurations that use light transmission, thermal or conducting vias 323, other circuit components 325 such as diodes, tracking sensors, and other devices, and conductors and pads 327. The thermal vias 323 can make contacts, preferably using thermal interface materials or solder, to heat sinks and/or heat pipes.

The multilayer board 360 is preferably made of a prior-art low-temperature cofired ceramic, high-temperature cofired ceramic, or printed circuit board or a similar board configuration and may contain multiple module components. In some embodiments of the converter module 300, a novel light cavity 370 may be formed on the multilayer board 360 and positioned directly below the photon-to-electricity conversion device 310. Bypass and blocking diodes (not shown) are preferably designed and incorporated to prevent the complete loss of power (which may occur in case a photon-to-electricity conversion cell fails or is shadowed). These can be embedded into the photon-to-electricity conversion device 310 or multilayer board 360 or panel of modules.

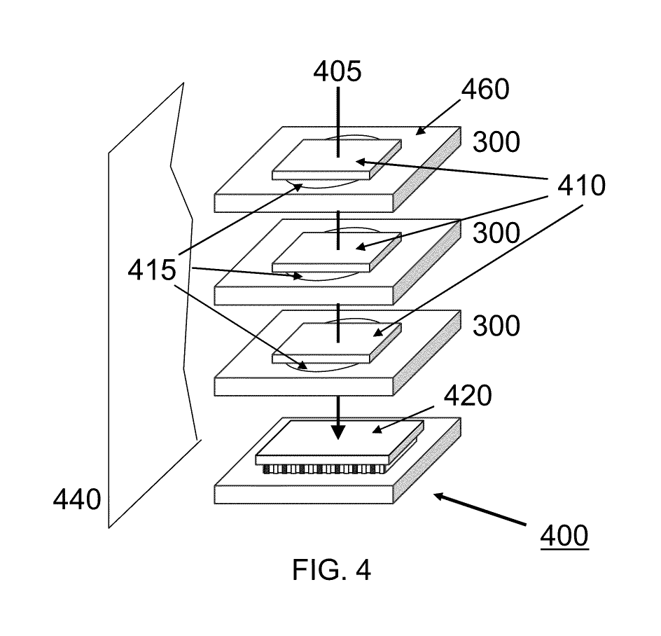

A first exemplary embodiment of a full converter module 400 is illustrated in FIG. 4 which includes a linear arrangement of multiple and separate sub-modules 300 at different positions in the flux path. This particular embodiment of a full converter module 400 thus includes multiple thin-layer photon-to-electricity devices 410 (each with its distinct junctions from other devices) and at least one heat-to-electricity device 420. In this configuration the latter is shown at the end of the cascade. Again, it will also be apparent to those skilled in the art that different numbers of such sub-modules could be employed depending on cost/performance requirements.

The incidence and reflectance of radiation (solar flux) 405 to the components 420 and 410 (of packaged sub-modules 300) is preferably at a right angle (90 degrees). Packaged sub-modules 300 shown in FIG. 4 are preferably the sub-modules of FIG. 3A having photon-to-electricity conversion cells of different band gaps and one or more heat-to-electricity devices within the flux path. The sub-modules are preferably positioned/arranged in a linear fashion to be in a transmission path of solar rays (but not in one monolithic die as in prior-art multi-junction cells or mechanically-stacked tandem cells) and the solar flux 405 is preferably transmitted from one packaged sub-module to the next one through a light cavity 415. In this arrangement, a photovoltaic device 410 in a first top packaged sub-module in a first position in the flux path absorbs photons of energy above its band gap from the incident solar flux and each subsequent device 410 in a different position preferably absorbs, in like manner, from the portion of the solar flux that is not absorbed by a previous device. The photon-to-electricity conversion devices 410 as noted above are of thin layers and are preferably mounted to a multilayer board (not shown) on an edge surface around the light cavity 415 that may be further supported by narrow grids (not shown) formed at the opening of the light cavity 415.

One main apparent advantage of the present invention over the prior art therefore lies in the fact that there is preferably some physical separation on the order of about a half of a millimeter to a centimeter between the conversion cells which results in increased overall module efficiency and the ability to handle larger flux concentrations. This physical separation will be a function of the particular application and can be tailored as required depending on specific system cost/performance requirements.

The cells also preferably are sized to have an area that is between a few hundred square microns to a few tens of centimeter squared depending on concentration factor and heat handling capability. The sequence of the packaged sub-modules, the selection of the p-n junction cell materials, and the cell layer thicknesses is preferably chosen such that the photovoltaic cells absorb and convert solar radiation (visible and maybe portions of infrared and ultraviolet) into electricity and the thermoelectric (or the thermionic cells) convert solar infrared and ultraviolet radiation and heat into electricity to maximize the overall conversion efficiency.

Casing 440 is a preferably a rigid assembly adapted to hold and position the packaged sub-modules in position for proper solar flux incidence and transmittance. The particular material/structure is not critical, and it will be understood that a variety of implementations will be possible depending on the particular components chosen for the conversion system. The packaged sub-modules 300 are preferably interconnected by ball grids, interposers, micro tubes, or similar contact mechanisms within the casing. The placement and connection of the packaged sub-modules 300 to the casing 440 may be achieved through slots, sockets, sliders, anchoring fasteners, tensioned springs, or similar contact mechanisms and, if necessary, through means of adjustment of sub-module positions.

Furthermore, while not shown specifically in FIG. 4, it will be apparent to those skilled in the art that a conventional mechanized control system can be implemented to physically adjust/alter a relative position and spacing between sub-modules. This can be done by any conventional motorized/mechanical means attached to frame 440, so that the entire conversion module's behavior can be adjusted/optimized as necessary based on an observed output. The output can be monitored by a conventional computing system (not shown) which analyzes the solar/electrical data and then provides appropriate feedback to the mechanical positioner.

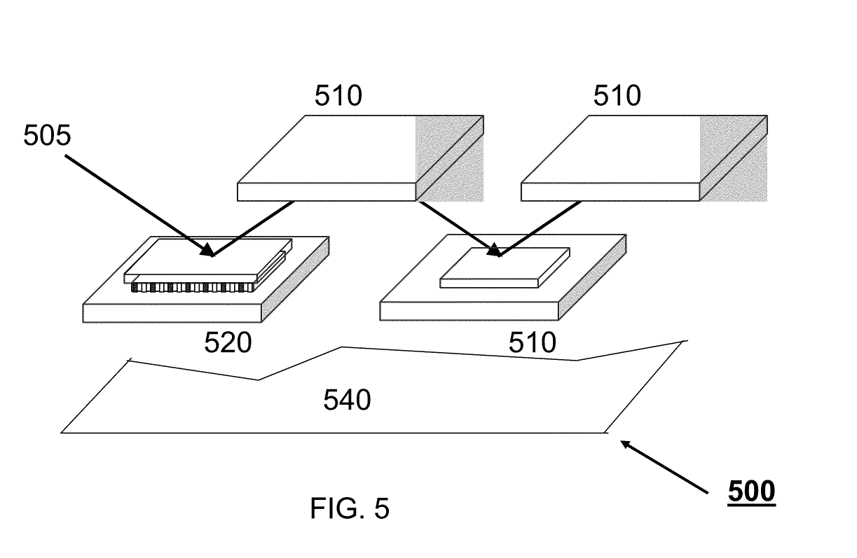

A second embodiment of a converter module 500 is illustrated in FIG. 5. This embodiment is similar to the previous embodiment 400 and has a number of corresponding components with the following exceptions. Instead of a direct solar ray transmission arrangement, the sub-modules 300 are arranged offset and opposite/facing each other. The incidence and reflectance of solar flux (or other radiation source) 505 to the packaged sub-modules of a heat-to-electricity conversion device 510 and photon-to-electricity conversion devices 520 are at oblique angles.

There is no light cavity required for solar transmittance and the module is adapted with reflectors (not shown, but which can be of any conventional form suitable for the sub-modules including a metallic layer within the cell) to guide the light between the sub-modules so as to impinge on devices 520 and 510. A back side of each photon-to-electricity or heat-to-electricity conversion device is preferably mounted entirely to a respective multilayer board and a heat sink/pipe.

Casing 540 is again an assembly adapted to hold and position the packaged sub-module 300 components 520 and 510 together for proper solar flux incidence, transmittance, and reflectance. As with the other embodiments described herein, the number of sub-modules in this particular form factor may be varied in accordance with the particular arrangement.

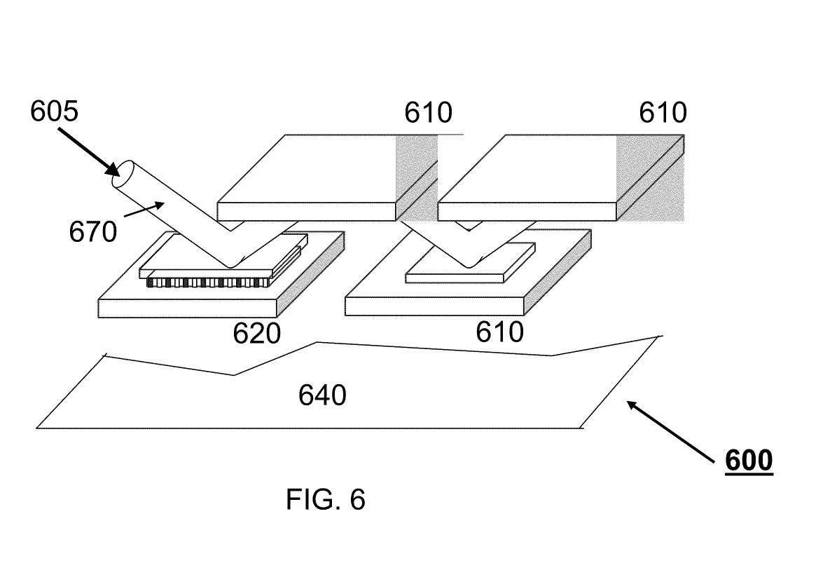

A third embodiment of a converter module 600 is illustrated in FIG. 6. This embodiment is similar to the previous embodiment 500 with the following exceptions. The incidence and reflectance of solar flux 605 to the packaged sub-module 300 components 620 and 610 are guided by one or more light tubes/guides/fiber/pipes 670. Again there is no light cavity required for solar transmittance. As before a back side of the photon-to-electricity 610 or heat-to-electricity 620 conversion devices is preferably mounted entirely to an associated multilayer board and a heat sink/pipe.

Casing 640 is again an assembly adapted to hold and position the packaged sub-modules together for proper solar flux incidence, transmittance, and reflectance. The light tube/guide/fiber/pipe 670 may be prior arts of a tube, a guide, a fiber, or a pipe in any shape or form with reflective or microscopic prisms coating or an optical guide or fiber in any shape or form for transporting light with minimal loss of solar light.

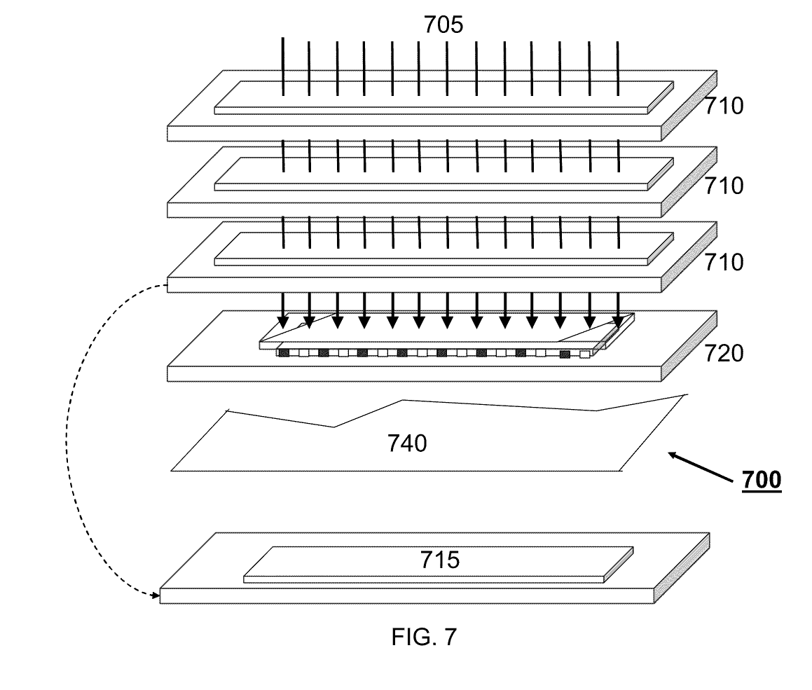

A fourth embodiment of a converter module 700 is illustrated in FIG. 7. This embodiment preferably receives the concentrated solar flux in a broad focal line 705 instead of a focal spot as in the previous embodiments. The focal line of solar flux 705 can be formed by a prior-art parabolic trough collector, a linear Fresnel lens, a hemispherical bowl collector, a cylindrical collector, or other known and contemplated equivalents. The focal line of solar flux 705 preferably enters the module through a slit or light cavity (not shown) guided with or without a light tube/guide/fiber/pipe in any shape or form.

The packaged sub-modules are preferably arranged with the thin-layer photon-to-electricity conversion devices 710 and a heat-to-electricity conversion device 720 aligned adjacent to each other and placed directly under slit (not shown) to receive the focal line of solar flux 705. This allows for a matrix of sub-modules 300 of any desired size, such as with N sub-modules in a width direction, and M sub-modules deep (with differing absorption characteristics as noted above) which results in a two dimensional array. Furthermore it will be understood as well that in this arrangement additional cells can be placed and paired orthogonally in a plane to a line connecting two more sub-modules so that the concentrated insolation flux is converted by a a three dimensional array into electrical energy. Other examples will be apparent to those skilled in the art.

As above casing 740 is an assembly adapted to hold and position the packaged sub-modules together for proper solar flux incidence, transmittance, and reflectance.

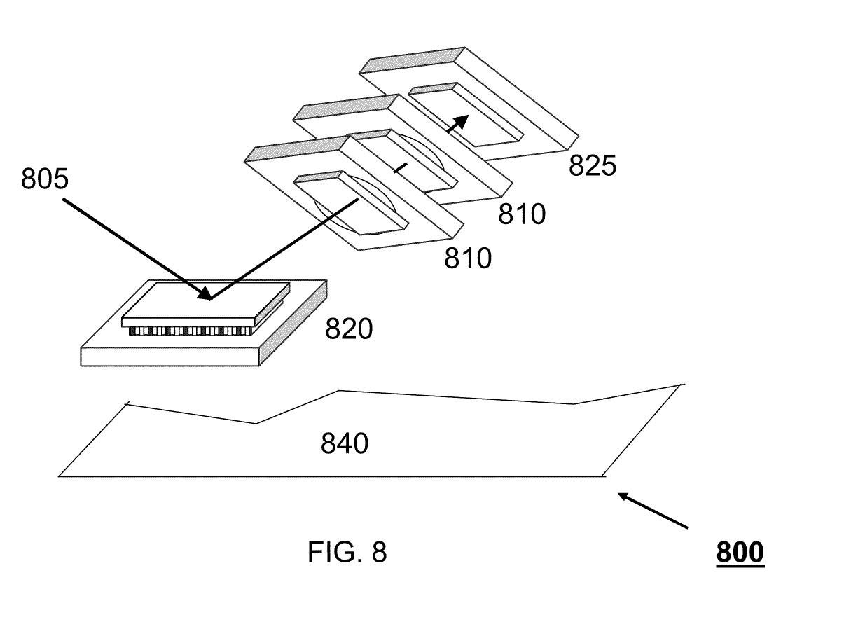

A fifth embodiment of a converter module 800 is illustrated in FIG. 8. This embodiment is similar to the previous embodiment 500 with the following exceptions. The incidence of solar flux 805 to the packaged sub-module of a heat-to-electricity conversion device 820 is reflected to and transmitted through multiple packaged sub-modules of thin-layer photon-to-electricity conversion devices 810 mounted to an associated multilayered board with light cavity with the exception of the terminating sub-module of a photon-to-electricity conversion device 825 which does not have a light cavity.

While not shown in FIG. 8, a heat-to-electricity conversion device 820 may be placed at the first incident position or the last terminating position, or at both first incident and the last terminating positions. Casing 840 is again an assembly adapted to hold and position the packaged sub-modules 820, 810, and 825 together for proper solar flux incidence, transmittance, and reflectance.

All of the aforementioned embodiments of conversion modules can be implemented within large scale solar power generation plants using concentrated light collection techniques. The present embodiments can also be mounted as part of an intelligent solar tracking system such as depicted in US Publication No. 2007/0227574 to Cart incorporated by reference herein. This latter system is for the most part cell/module agnostic and could benefit from incorporating the conversion modules of the present invention.

The embodiments described herein provide a number of benefits including at least the following for solar electricity generation:

1) improved conversion efficiency resulting from integrating specially arranged photovoltaic and thermionic or thermoelectric devices into different conversion module configurations such that the majority of the photons in the solar spectrum and some of the heat generated from the interactions between photons and matters (e.g. non-radiative recombination, excess energy) are used in the conversion to electricity;

2) improved concentration factor by using photovoltaic cells of a single crystal to avoid thermal stress and by enhancing thermal management using the integration scheme in (1);

3) can provide a true low-cost mass production with consistent yield by:

a) combining both high conversion efficiency (1) and high concentration factor (2) into a single conversion system,

b) using a low cost liquid-phase epitaxy method, gas diffusion, or similar material growth methods for the formation of materials in the conversion devices,

c) using the cofired ceramic or similar multilayer boards for the packaging of the photovoltaic and thermoelectric or themionic devices into a unit module.

d) using solar collectors, light tubes/guides/fibers/pipes, and standard components which are readily available for day-lighting, optical communication, and other applications,

e) using proven wafer processing and packaged assembly methods developed and manufactured in the semiconductor, microelectronics, and/or solar industry.

4) provides flexibility in design configurations that may encompass different types of conversion devices that may be made of single p-n junction, double p-n junctions, or multiple p-n junctions, solar collectors, solar concentrators, light tubes/guides/fibers/pipes, and heat sinks/pipes to meet a given set of solar power generation requirements.

It is expected that embodiments of the present invention can result in newer generations of power facilities that can achieve greater than 0.4 MW per acre.

It will be apparent to those skilled in the art that the above is not intended to be an exhaustive description of every embodiment which can be rendered in accordance with the present teachings. Other embodiments could be constructed which use a combination of features from the above described exemplary forms, such as an embodiment which uses a mixture of focal lines/focal spots, direct transmission and reflectance, and varying combinations of light tubes/guides/fibers/pipes, light cavities, etc.

Accordingly the present disclosure will be understood by skilled artisans to describe and enable a number of such variants as well. While the present invention is depicted using solar flux as a radiation source, it will be apparent that the present teachings could be used in any environment where it is desirable to optimize a radiation/electrical conversion process, particularly those involving high intensity radiation.

What is claimed is:

1. A solar-to-electricity conversion submodule comprising:
a. a photon-to-electricity conversion device;
b. a heat sink/pipe coupled to said photon-to-electricity conversion device;
c. a multi-layer board having a light cavity for receiving or transmitting radiation flux associated with said photon-to-electricity conversion device;
d. one more conductive leads coupled to said photon-to-electricity conversion device for providing an electrical output in response to radiation flux impinging on said photon-to-electricity conversion device;
wherein said photon-to-electricity conversion device, heat sink/pipe and conductive leads are located on and housed by said multi-layer board.

2. The submodule of claim 1 wherein said photon-to-electricity device is based on a single junction cell adapted to convert only a first portion of an insolation flux spectrum into electrical energy based on a first band gap energy.

3. The submodule of claim 2, wherein said module is further adapted to be stacked into a cascade with one or more second modules having one or more photon-to-electricity devices based on single junction cells adapted to convert a second different portion of said insolation flux spectrum into electrical energy based on one or more second band gap energies.

4. The submodule of claim 3, wherein said cascade is arranged in a linear arrangement such that said insolation flux travels in a straight line.

5. The submodule of claim 3, wherein said cascade is arranged in an offset arrangement such that said insolation flux is refracted and reflected between different photon-electricity devices as it travels.

6. The submodule of claim 1 wherein said multi-layer board is further adapted to mount a thermionic or thermoelectric device in lieu of said photon-to-electricity device.

7. The submodule of claim 1 wherein said multi-layer board is further adapted to mount a thermionic or thermoelectric device in addition to said photon-to-electricity device.

8. The submodule of claim 1 wherein said multi-layer board is comprised of a co-fired ceramic.

9. The submodule of claim 1 wherein said multi-layer board includes conducting thermal vias.

10. The submodule of claim 1 wherein said multi-layer board includes embedded thermal diodes.

11. The submodule of claim 1 wherein said multi-layer board includes embedded bypass and/or blocking diodes.

12. The submodule of claim 1 wherein said multi-layer board includes embedded sensors and related electronic circuitry.

13. The submodule of claim 1 wherein said photon-to-electricity device includes single layer or multilayers of absorptive or anti-reflection costings for raising the absorption of a selective spectrum of the radiation flux that is converted into electricity.

14. The submodule of claim 1 wherein said photon-to-electricity device includes a reflection coating for reflecting a remaining radiation flux that is not converted into electricity.

15. The submodule of claim 1 wherein said multi-layer board is further adapted to couple to a light tube, a light guide or light pipe to receive said radiation flux.

16. The submodule of claim 1 wherein a plurality of photon-to-electricity devices having the same spectrum conversion capability are arranged within the same plane and in a line to receive said radiation flux in a broad focal line.

17. The submodule of claim 16 wherein said plurality of photon-to-electricity devices receive said radiation flux through a slit or light cavity mounted on said multi-layer board.

18. A solar-to-electricity conversion submodule comprising:
a. a photon-to-electricity conversion device adapted to convert insolation flux into electricity;
b. a thermionic and/or thermoelectric device situated adjacent to said photon-to-electricity device and adapted to convert heat energy associated with such photon-to-electricity device into electricity;
c. heat sinks/pipes coupled to said photon-to-electricity conversion device and said thermionic and/or thermoelectric device;
d. a multi-layer board having a light cavity for receiving or transmitting insolation flux;
e. an electrical combiner circuit coupled to both said photon-to-electricity conversion device and said thermionic and/or thermoelectric device and adapted to generate an electrical output in response to said insolation flux;
wherein said photon-to-electricity conversion device, thermionic and/or thermoelectric device, heat sink/pipe and electrical combiner circuit are located on and housed by or attached to said multi-layer board.

19. The submodule of claim 1 wherein a position of said thermionic and/or thermoelectric device can be automatically adjusted.

20. The submodule of claim 1 wherein said multi-layer board has a thermal expansion characteristic matching said photon to electricity conversion device.

21. A solar-to-electricity conversion submodule comprising:
a. at least one photon-to-electricity conversion device having a single junction cell for converting only a first portion of an incident radiation spectrum into electricity;
b. a heat sink/pipe coupled to said photon-to-electricity conversion device;
c. a multi-layer board having a light cavity for receiving or transmitting radiation flux associated with said photon-to-electricity conversion device;
wherein said multi-layer board is adapted to have a thermal expansion characteristic that substantially matches said photon-to-electricity conversion device;
d. one more conductive leads coupled to said photon-to-electricity conversion device for providing an electrical output in response to radiation flux impinging on said photon-to-electricity conversion device;
wherein said photon-to-electricity conversion device, heat sink/pipe and conductive leads are located on and housed by or attached to said multi-layer board.
